(19) United States
(12) Patent Application Publication
(10) Pub. No.: US 2004/0155714 A1
(43) Pub. Date: Aug. 12, 2004

(54) Oscillation circuit

(76) Inventors: Kazuhiko Nishikawa, Osaka (JP); Seiji Watanabe, Kyoto (JP); Takahiro Bokui, Osaka (JP)

Correspondence Address: WENDEROTH, LIND & PONACK, L.L.P., 2033 K STREET N. W., SUITE 800, WASHINGTON, DC, 20006-1021, US

(21) Appl. No.: 10/757,598

(22) Filed: Jan. 15, 2004

(30) Foreign Application Priority Data
Jan. 15, 2003 (JP) 2003-007558

(51) Int. Cl. H03B 1/00

(52) U.S. Cl. 331/57

(57) ABSTRACT

An oscillation circuit comprises a plurality of constant current supplies for outputting a constant current according to a voltage supplied from a control current terminal; a plurality of switching elements which are charged or discharged by the constant current outputted from the constant current supplies and are turned on or off when exceeding a predetermined threshold voltage; and restriction elements for restricting a charging target voltage or a discharging target voltage at nodes between the constant current supplies and the switching elements to a constant value.

### FIELD OF THE INVENTION

The present invention relates to an oscillation circuit and, more particularly, to an oscillation circuit to be used in a PLL circuit that is required in a digital recording/playback apparatus or the like, and is available in a wide frequency band.

### BACKGROUND OF THE INVENTION

A conventional oscillation circuit employs, as delay circuits, inverter circuits in which PMOS transistors and NMOS transistors for restricting current values to a power supply side and a GND side are inserted so that a delay time can be controlled by a control voltage, and the delay circuits are cascade-connected in a ring shape (please refer to “CMOS analog circuit design technique”, supervised by Atsushi Iwata, edited by the planning department of TRICEPS Co. Ltd.).

Hereinafter, the construction and operation of a conventional oscillation circuit will be described with reference to FIGS. 12 to 17 FIG. 12 is a diagram illustrating an example of a circuit structure of a conventional oscillation circuit.

With reference to FIG. 12, the conventional oscillation circuit is constituted by constant current supplies comprising PMOS transistors that are controlled by a voltage supplied from a current control terminal 2, and switching elements comprising NMOS transistors that are charged by a constant current outputted from the constant current supply and are turned on when exceeding a threshold voltage. In the conventional oscillation circuit, the magnitude of the ronstant current is changed by changing the voltage supplied from the current control terminal 2, thereby to change the length of a period during which the switching elements are charged up to the threshold voltage, and thus an oscillation cycle T is changed.

Hereinafter, the construction of the oscillation circuit will be described in more detail. In FIG. 12, MP1, MP2, and MP3 are PMOS transistors, and MN1, MN2, and MN3 are NMOS transistors. The gates of the PMOS transistors MP1, MP2, and MP3 are connected to the current control terminal 2, and the sources thereof are connected to the power supply, and further, the sources of the NMOS transistors MN1, MN2, and MN3 are connected to the GND. The drain of the NMOS transistor MN1 is connected to the drain of the PMOS transistor MP1 at a node A1, thereby constituting a first delay circuit having the gate input of the NMOS transistor MN1 as its input and the node A1 as its output. Likewise, the PMOS transistor MP2 and the NMOS transistor MN2 constitute a second delay circuit, and the PMOS transistor MP3 and the NMOS transistor MN3 constitute a third delay circuit.

The first to third delay circuits are cascade-connected so that the output A1 of the first delay circuit is connected to the input of the second delay circuit, the output A2 of the second delay circuit is connected to the input of the third delay circuit, and the output A3 of the third delay circuit is connected to the input of the first delay circuit.

The operation of the conventional oscillation circuit constituted as described above will be described with reference to timing charts shown in FIG. 13. FIG. 13 is a diagram illustrating operation timing charts of the nodes A1, A2, and A3 in the conventional oscillation circuit shown in FIG. 12. In FIG. 13, alternate long and short dashed lines indicate threshold voltages of the NMOS transistors MN1, MN2, and MN3.

Initially, the PMOS transistors MP1, MP2, and MP3 as constant current supplies pass a constant current according to the voltage supplied from the current control terminal 2. For simplification, it is assumed that the oscillation circuit is in its ideal state where the transition time in which the voltages at the respective nodes A1, A2, and A3 change from the power supply voltage to the threshold voltages of the MN1, MN2, and MN3 or below is zero.

As shown in FIG. 13, since, at time t1, the voltage at the node A1 exceeds the threshold voltage of the NMOS transistor MN2, the NMOS transistor MN2 is turned on, and the voltage at the node A2 becomes equal to or lower than the threshold voltage at the turn-on of the NMOS transistor MN2. Then, the NMOS transistor MN3 is turned off when the voltage at the node A2 becomes equal to or lower than the threshold voltage, and charging of the node A3 by the constant current outputted from the PMOS transistor MP3 is started.

In a period from t2 to t3, the node A3 is charged by the constant current outputted from the PMOS transistor MP3 continuously from the previous period (t1 to t2). Since, at time t2 that is the starting point of this period, the voltage at the node A3 exceeds the threshold voltage of the NMOS transistor MN1, the NMOS transistor MN1 is turned on, and the voltage at the node A1 becomes equal to or lower than the threshold voltage at the turn-on of the NMOS transistor MN1. Then, the NMOS transistor MN2 is turned off when the voltage at the node A1 becomes equal to or lower than the threshold voltage, and charging of the node A2 by the constant current outputted from the PMOS transistor MP2 is started.

During a period from t3 to t4, the node A2 is charged by the constant current outputted from the PMOS transistor MP2, continuously from the previous period (t2 to t3). Since, at time t3 that is the starting point of this period, the voltage at the node A2 exceeds the threshold voltage of the NMOS transistor MN3, the NMOS transistor is turned on, and the voltage at the node A3 becomes equal to or lower than the threshold voltage at the turn-on of the NMOS transistor MN3. Since the NMOS transistor MN1 is turned off when the voltage of the node A3 becomes equal to or lower than the threshold voltage, charging of the node A1 by the constant current outputted from the PMOS transistor MP1 is started. Thereafter, the operation performed during the period from t1 to t4 is repeated, whereby the oscillation circuit oscillates at a cycle T.

In this way, the oscillation cycle T is equal to a period obtained by summing the respective periods during which the respective NMOS transistors MN1, MN2, and MN3 are charged by the constant currents outputted from the respective PMOS transistors MP1, MP2, and MP3 according to the voltage supplied from the current control terminal 2, and exceed the threshold voltage.

Accordingly, when the voltage supplied from the current control terminal 2 is changed to change the constant currents outputted from the respective PMOS transistor MP1, MP2, and MP3, the lengths of the respective periods (t1˜t2, t2˜t3, t3˜t4) until the respective NMOS transistors MN1, MN2, and MN3 are charged to the threshold voltage can be changed, whereby the oscillation cycle T as the total of these periods can be changed.

In FIG. 13, “V” is a charging target voltage to which the nodes A1 to A3 between the constant current supplies MP1 to MP3 and the switching elements MN1 to MN3 should be charged by the constant current outputted from the constant current supplies MP1, MP2, and MP3, respectively, and this charging target voltage V changes depending on the oscillation cycle T. FIG. 15 is a diagram illustrating the oscillation characteristics of the conventional oscillation circuit in its ideal state. In FIG. 15, the abscissa shows the constant current flowing through the PMOS transistors MP1, MP2, and MP3, and the ordinate shows the oscillation frequency that is the reciprocal of the oscillation cycle T. As shown in FIG. 15, when the oscillation cycle T is long, the charging target voltage V is lowered because the constant current for charging the respective nodes is small. Conversely, when the oscillation cycle T is short, the charging target voltage V is high because the constant current is large.

In the above description for the operation, the transition time during which the voltages at the respective nodes A1, A2, and A3 change from the charging target voltage V to the threshold voltage is zero, and the voltages at the respective nodes A1, A2, and A3 becomes equal to or lower than the threshold voltage when the NMOS transistors MN1, MN2, and MN3 are turned on. However, there is actually required a transition time during which the voltages at the respective nodes A1, A2, and A3 change from the charging target voltage V to the threshold voltage or below, as shown in FIG. 14. FIG. 14 is a diagram illustrating an operation timing chart at the node A3 that is obtained when the transition time during which the voltages at the node A1, A2, or A3 change from the charging target voltage to the threshold voltage or below is considered. In FIG. 14, “ΔT” is a time required for the voltage at the node A3 to change from the charging target voltage V to the threshold voltage of the NMOS transistor MN1 or below. That is, in the ideal state shown in FIG. 13, at time t3, the NMOS transistor NM3 is turned on and, simultaneously, the voltage at the node A3 becomes equal to or lower than the threshold voltage, and charging of the node A1 by the constant current outputted from the PMOS transistor MP1 is started. Actually, as shown in FIG. 14, the NMOS transistor MN3 is turned on at time t3, and the voltage of the node A3, which is at the charging target voltage V, starts to be lowered from the turn-on of the NMOS transistor MN3. At time t3′ when the transition time ΔT has passed from time t3, the voltage at the node A3 becomes equal to or lower than the threshold voltage of the NMOS transistor MN1. Since, the NMOS transistor MN1 is turned off when the voltage at the node A3 becomes equal to or lower than the threshold voltage, charging of the node A1 by the constant current outputted from the PMOS transistor MP1 is started from time t3′.

Accordingly, the actual oscillation cycle T′ is expressed by T′=(period from t1 to t2+ΔT)+(period from t2 to t3+ΔT)+(period from t3 to t4+ΔT)

Therefore, in contrast to the ideal oscillation cycle T that is obtained without considering the transition time ΔT during which the respective nodes A1 to A2 change from the charging target voltage V to the threshold voltage or below, the actual oscillation cycle T′ is

T′=T+3*ΔT

As described above, the transition time ΔT is the time required until the voltages at the respective nodes A1, A2, and A3 change from the charging target voltage V to the threshold voltage of the NMOS transistors MN1, MN2, and MN3 or below. As shown in FIG. 16, when the oscillation cycle T1 is short, the charging target voltage V1 is high, and the transition time ΔT1 becomes long. Conversely, when the oscillation cycle T2 is long, the charging target voltage V2 is low, and the transition time ΔT2 becomes short.

Accordingly, in the conventional oscillation circuit, when the transition time ΔT is considered, the transition time ΔT changes depending on the oscillation cycle T, and the oscillation cycle T changes depending on the constant current flowing through the PMOS transistors MP1, MP2, and MP3, and therefore, the linearity of the oscillation frequency against the constant current is deteriorated as shown in FIG. 17.

As described above, in the conventional oscillation circuit, the charging target voltage V changes when the oscillation cycle T is changed, and therefore, the transition time ΔT during which the voltages at the respective nodes A1 to A3 change from the charging target voltage V to the threshold voltage undesirably changes depending on the oscillation cycle T. Since this oscillation cycle T depends on the constant current that is output from the PMOS transistors as constant current supplies, as the linearity of the oscillation frequency against the constant current is deteriorated as shown in FIG. 17.

### SUMMARY OF THE INVENTION

The present invention is made to solve the above-described problems and has for its object to provide an oscillation circuit which has an improved linearity of the oscillation frequency against the constant current and has a broad oscillation frequency range, by making the charging target voltage V at each node constant regardless of the oscillation frequency T.

Other object and advantages of the invention will become apparent from the detailed description that follows. The detailed description and specific embodiments described are provided only for illustration since various additions and modifications within the scope of the invention will be apparent to those of skill in the art from the detailed description.

According to a first aspect of the present invention, there is provided an oscillation circuit comprising a plurality of constant current supplies for outputting a constant current according to a voltage supplied from a control current terminal, and a plurality of switching elements which are charged or discharged by the constant current outputted from the constant current supplies and are turned on or off when exceeding a predetermined threshold voltage, wherein the voltage from the control current terminal is changed to change a time required until the switching elements are charged or discharged to the threshold voltage, thereby changing an oscillation cycle, and the oscillation circuit further include restriction elements of restricting a charging target voltage or a discharging target voltage at nodes between the constant current supplies and the switching elements to a constant value. Therefore, it is possible to keep the charging target voltage or the discharging target voltage at the node between the constant current supply and the switching element constant regardless of the oscillation frequency, thereby providing an oscillation circuit that can maintain linear oscillation characteristics even when the oscillation frequency range is increased.

According to a second aspect of the present invention, in the oscillation circuit according to the first aspect, the restriction elements comprise NMOS transistors or PMOS transistors. Therefore, restriction of the charging target voltage or the discharging target voltage at the node between the constant current supply and the switching element to a constant value regardless of the oscillation frequency can be realized with efficiency, without increasing the circuit scale.

According to a third aspect of the present invention, in the oscillation circuit according to the first aspect, the restriction elements comprise at least one resistor. Therefore, restriction of the charging target voltage or the discharging target voltage at the node between the constant current supply and the switching element to a constant value regardless of the oscillation frequency can be realized without increasing the circuit scale.

According to a fourth aspect of the present invention, there is provided an oscillation circuit comprising: a first delay circuit in which a drain of a PMOS transistor MP1 having a current control terminal as its gate input and a power supply as its source input is connected to a drain of an NMOS transistor MN4, a gate input of the NMOS transistor MN4 is connected to the power supply, a source of the NMOS transistor MN4 and a drain of the NMOS transistor MN1 are connected at a node A1, and a source of the NMOS transistor MN1 is connected to a GND, said first delay circuit having a gate input of the NMOS transistor MN1 as its input and the node A1 as its output; a second delay circuit in which a drain of a PMOS transistor MP2 having the current control terminal as its gate input and the power supply as its source input is connected to a drain of an NMOS transistor MN5, a gate input of the NMOS transistor MN5 is connected to the power supply, a source of the NMOS transistor MN5 and a drain of the NMOS transistor MN2 are connected at a node A2, and a source of the NMOS transistor MN2 is connected to a GND, said second delay circuit having a gate input of the NMOS transistor MN2 as its input and the node A2 as its output; and a third delay circuit in which a drain of a PMOS transistor MN3 having the current control terminal as its gate input and the power supply as its source input is connected to a drain of an NMOS transistor MN6, a gate input of the NMOS transistor MN6 is connected to the power supply, a source of the NMOS transistor MN6 and the drain of the NMOS transistor MN3 are connected at a node A3, and a source of the NMOS transistor MN3 is connected to a GND, said third delay circuit having a gate input of the NMOS transistor MN3 as its input and the node A3 as its output; and the first to third delay circuits are cascade-connected so that the output A1 of the first delay circuit is connected to the input of the second delay circuit, the output A2 of the second delay circuit is connected to the input of the third delay circuit, and the output A3 of the third delay circuit is connected to the input of the first delay circuit. Therefore, the possible upper-limit voltage of the nodes A1, A2, and A3 is restricted to a voltage that is lower than the power supply voltage by the threshold voltage Vt of the NMOS transistors MN4, MN5, and MN6, by the NMOS transistor MN4, MN5, and MN6 whose gate inputs are fixed to the power supply, whereby the charging target voltage of the nodes A1, A2, and A3 can be restricted, resulting in an oscillation circuit having linear oscillation characteristics even when the oscillation frequency range is increased.

According to a fifth aspect of the present invention, in the oscillation circuit according to the fourth aspect, the gate inputs of the NMOS transistors MN4, MN5, and MN6 are fixed to an arbitrary constant voltage. Therefore, the possible upper-limit voltage of the nodes A1, A2, and A3 is restricted to a voltage that is lower than the arbitrary constant voltage by the threshold voltage Vt of the NMOS transistors MN4, MN5, and MN6, by the NMOS transistor MN4, MN5, and MN6 whose gate inputs are fixed to the arbitrary constant voltage, whereby the charging target voltage of the nodes A1, A2, and A3 can be restricted, resulting in an oscillation circuit having linear oscillation characteristics even when the oscillation frequency range is increased.

According to a sixth aspect of the present invention, there is provided an oscillation circuit comprising: a first delay circuit in which a drain of an NMOS transistor MN1 having a current control terminal as its gate input and a GND as its source input is connected to a drain of a PMOS transistor MP4, a gate input of the PMOS transistor MP4 is connected to the GND, a source of the PMOS transistor MP4 and a drain of the PMOS transistor MP1 are connected at a node A1, and a source of the PMOS transistor MP1 is connected to a power supply, said first delay circuit having a gate input of the PMOS transistor MP1 as its input and the node A1 as its output; a second delay circuit in which a drain of an NMOS transistor MN2 having the current control terminal as its gate input and the GND as its source input is connected to a drain of a PMOS transistor MP5, a gate input of the PMOS transistor MP5 is connected to the GND, a source of the PMOS transistor MP5 and a drain of the PMOS transistor MP2 are connected at a node A2, and a source of the PMOS transistor MP2 is connected to a power supply, said second delay circuit having a gate input of the PMOS transistor MP2 as its input and the node A2 as its output; and a third delay circuit in which a drain of an NMOS transistor MN3 having the current control terminal as its gate input and the GND as its source input is connected to a drain of a PMOS transistor MP6, a gate input of the PMOS transistor MP6 is connected to the GND, a source of the PMOS transistor MP6 and the drain of the PMOS transistor MP3 are connected at a node A3, and a source of the PMOS transistor MP3 is connected to a power supply, said third delay circuit having a gate input of the PMOS transistor MP3 as its input and the node A3 as its output; and the first to third delay circuits are cascade-connected so that the output A1 of the first delay circuit is connected to the input of the second delay circuit, the output A2 of the second delay circuit is connected to the input of the third delay circuit, and the output A3 of the third delay circuit is connected to the input of the first delay circuit Therefore, the possible lower-limit voltage of the nodes A1, A2, and A3 is restricted to a voltage that is higher than the GND by the threshold voltage Vt of the PMOS transistors MP4, MP5, and MP6, by the PMOS transistor MP4, MP5, and MP6 whose gate inputs are fixed to the GND, whereby the discharging target voltage of the nodes A1, A2, and A3 can be restricted, resulting in an oscillation circuit having linear oscillation characteristics even when the oscillation frequency range is increased.

According to a seventh aspect of the present invention, in the oscillation circuit according to the sixth aspect, the gate inputs of the PMOS transistors MP4, MP5, and MP6 are an arbitrary constant voltage. Therefore, the possible lower-limit voltage of the nodes A1, A2, and A3 is restricted to a voltage that is higher than the arbitrary constant voltage by the threshold voltage Vt of the PMOS transistors MP4, MP5, and MP6, by the PMOS transistor MP4, MP5, and MP6 whose gate inputs are fixed to the arbitrary constant voltage, whereby the discharging target voltage of the nodes A1, A2, and A3 can be restricted, resulting in an oscillation circuit having linear oscillation characteristics even when the oscillation frequency range is increased.

According to an eighth aspect of the present invention, there is provided an oscillation circuit comprising: a first delay circuit in which a drain of a PMOS transistor MP1 having a current control terminal as its gate input and a power supply as its source input is connected to a drain of an NMOS transistor MN13, a drain of a PMOS transistor MP2 having the current control terminal as its gate input and the power supply as its source input is connected to a drain of an NMOS transistor MN14, gate inputs of the NMOS transistors MN13 and MN14 are connected to the power supply, a source of the NMOS transistor MN13 and drains of NMOS transistors MN1 and MN2 are connected at a node A1, and a source of the NMOS transistor MN14 and drains of NMOS transistor MN4 and MN3 are connected at a node A2, and the sources of the NMOS transistors MN1, MN2, MN3, and MN4 arc connected to a GND, said first delay circuit having a gate input of the NMOS transistor MN1 as its positive side input, the gate input of the NMOS transistor MN4 as its negative side input, the node A1 as its negative side output, and the node A2 as its positive side output; a second delay circuit in which a drain of a PMOS transistor MP3 having the current control terminal as its gate input and the power supply as its source input is connected to a drain of an NMOS transistor MN15, a drain of a PMOS transistor MP4 having the current control terminal as its gate input and the power supply as its source input is connected to a drain of an NMOS transistor MN16, gate inputs of the NMOS transistors MN15 and MN16 are connected to the power supply, a source of the NMOS transistor MN15 and drains of NMOS transistors MN5 and MN6 are connected at a node A3, a source of the NMOS transistor MN16 and drains of NMOS transistor MN7 and MN8 are connected at a node A4, and the sources of the NMOS transistors MN5, MN6, MN7, and MN8 are connected to a GND, said second delay circuit having the gate input of the NMOS transistor MN5 as its positive side input, the gate input of the NMOS transistor MN8 as its negative side input, the node A3 as its negative side output, and the node A4 as its positive side output; and a third delay circuit in which a drain of a PMOS transistor MP5 having the current control terminal as its gate input and the power supply as its source input is connected to a drain of an NMOS transistor MN17, a drain of a PMOS transistor MP6 having the current control terminal as its gate input and the power supply as its source input is connected to a drain of an NMOS transistor MN18, gate inputs of the NMOS transistors MN17 and MN18 are connected to the power supply, a source of the NMOS transistor MN17 and drains of NMOS transistors MN9 and MN10 are connected at a node A5, a source of the NMOS transistor MN18 and drains of NMOS transistor MN11 and MN12 are connected at a node A6, and the sources of the NMOS transistors MN9, MN10, MN11, and MN12 are connected to a GND, said third delay circuit having the gate input of the NMOS transistor MN9 as its positive side input, the gate input of the NMOS transistor MN12 as its negative side input, the node A5 as its negative side output, and the node A6 as its positive side output; and the first to third delay circuits being cascade-connected such that the negative side output A1 of the first delay circuit is connected to the positive side input of the second delay circuit, and the positive side output A2 of the first delay circuit is connected to the negative side input of the second delay circuit, the negative side output A3 of the second delay circuit is connected to the positive side input of the third delay circuit, and the positive side output A4 of the second delay circuit is connected to the negative side input of the third delay circuit, and the negative side output A5 of the third delay circuit is connected to the positive side input of the first delay circuit, and the positive side output A6 of the third delay circuit is connected to the negative side input of the first delay circuit. Therefore, the possible upper-limit voltage of the nodes A1, A2, A3, A4, A5, and A6 is restricted to a voltage that is lower than the power supply voltage by the threshold voltage Vt of the NMOS transistors MN13, MN14, MN15, MN16, MN17, and MN18, by the NMOS transistor MN13, MN14, MN15, MN16, MN17, and MN18 whose gate inputs are fixed to the power supply, whereby the charging target voltage of the nodes A1, A2, A3, A4, A5, and A6 can be restricted, resulting in an oscillation circuit having linear oscillation characteristics even when the oscillation frequency range is increased.

According to a ninth aspect of the present invention, in the oscillation circuit according to the eighth aspect, the gate inputs of the NMOS transistors MN13, MN14, MN15, MN16, MN17, and MN18 are an arbitrary constant voltage. Therefore, the possible upper-limit voltage of the nodes A1, A2, A3, A4, A5, and A6 is restricted to a voltage that is lower than the arbitrary constant voltage by the threshold voltage Vt of the NMOS transistors MN13, MN14, MN15, MN16, MN17., and MN18, by the NMOS transistor MN13, MN14, MN15, MN16, MN17, and MN18 whose gate inputs are fixed to the arbitrary constant voltage, whereby the charging target voltage of the nodes A1, A2, A3, A4, A5, and A6 can be restricted, resulting in an oscillation circuit having linear oscillation characteristics even when the oscillation frequency range is increased.

According to a tenth aspect of the present invention, in the oscillation circuit according to any of the fourth to ninth aspects, the number of the delay circuits to be cascade-connected is N (N: integer equal to or larger than 2). Therefore, the charging target voltage or the discharging target voltage at the node can be restricted by the constant current regardless of the number of stages of the delay circuits, thereby providing an oscillation circuit having linear oscillation characteristics even when the oscillation frequency range is increased.

### BRIEF DESCRIPTION OF THE DRAWINGS

FIG. 1 is a diagram illustrating an oscillation circuit according to a first embodiment of the present invention.

FIG. 2 is a timing chart illustrating the operation of the oscillation circuit of the first embodiment in its ideal state.

FIG. 3 is a timing chart illustrating the actual operation of the oscillation circuit according to the first embodiment.

FIG. 4 is a diagram illustrating the oscillation characteristics of the oscillation circuit according to the first embodiment.

FIG. 5 is a diagram illustrating another construction of the oscillation circuit according to the first embodiment.

FIG. 6 is a diagram illustrating another construction of the oscillation circuit according to the first embodiment.

FIG. 7 is a diagram illustrating an oscillation circuit according to a second embodiment of the present invention.

FIG. 8 is a timing chart illustrating the operation of the oscillation circuit of the second embodiment in its ideal state.

FIG. 9 is a timing chart illustrating the actual operation of the oscillation circuit according to the second embodiment.

FIG. 10 is a diagram illustrating an oscillation circuit according to a third embodiment of the present invention.

FIG. 11 is a timing chart illustrating the operation of the oscillation circuit of the third embodiment in its ideal state.

FIG. 12 is a diagram illustrating an example of a conventional oscillation circuit.

FIG. 13 is a timing chart illustrating the operation of the conventional oscillation circuit in its ideal state.

FIG. 14 is a timing chart illustrating the actual operation of the conventional oscillation circuit.

FIG. 15 is a diagram illustrating the oscillation characteristics of the conventional oscillation circuit in its ideal state.

FIG. 16 is a diagram illustrating charging target voltages V1 and V2 and transition times ΔT1 and ΔT2 when oscillation cycles of the conventional oscillation circuit are T1 and T2, respectively.

FIG. 17 is a diagram illustrating the actual oscillation characteristics of the conventional oscillation circuit.

### DETAILED DESCRIPTION OF THE PREFERRED EMBODIMENTS

[Embodiment 1]

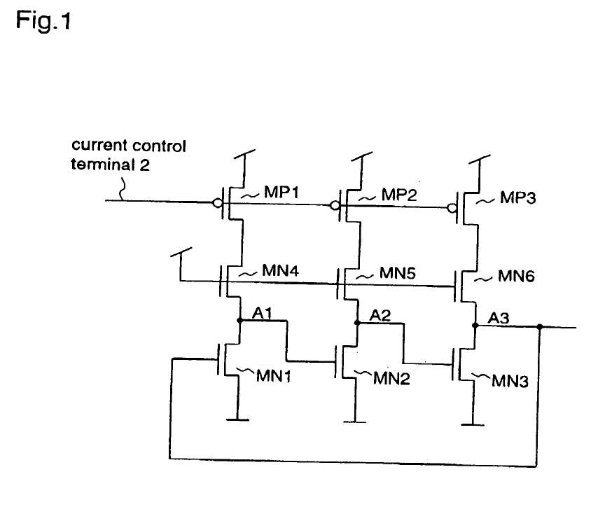

Hereinafter, a first embodiment of the present invention will be described with reference to FIGS. 1 to 4.

Initially, the construction of an oscillation circuit according to the first embodiment will be described with reference to FIG. 1. FIG. 1 is a diagram illustrating the circuit structure of the oscillation circuit according to the first embodiment.

As shown in FIG. 1, the oscillation circuit according to the first embodiment is constituted by a constant current supply comprising PMOS transistors MP1, MP2, and MP3 which are controlled by a voltage supplied from a current control terminal 2, and a switching element comprising NMOS transistors which are charged by the constant current outputted from the constant current supplies and are turned on when exceeding a threshold voltage. In the oscillation circuit so constructed, the length of a period during which the switching elements are charged up to the threshold voltage is changed by changing the voltage supplied from the current control terminal 2, thereby to change the oscillation cycle T of the oscillation circuit, and a restriction element for restricting the charging target voltage based on the constant current outputted from the constant current supply to a constant value regardless of the oscillation cycle T is provided between each constant current supply and each switching element.

Hereinafter, the construction of the oscillation circuit will be described in detail. In tile oscillation circuit according to the first embodiment, the drain of the PMOS transistor MP1 having the current control terminal 2 as its gate input and the power supply as its source input is connected to the drain of the NMOS transistor MN4 that is a restriction element, the gate input of the NMOS transistor MN4 is connected to the power supply, the source of the NMOS transistor MN4 and the drain of the NMOS transistor MN1 as a switching element are connected at a node A1, and the source of the NMOS transistor MN1 is connected to the GND, thereby constituting a first delay circuit having the gate input of the NMOS transistor MN1 as its input and the node A1 as its output. Likewise, the PMOS transistor MP2 that is a constant current supply having the current control terminal 2 as its gate input and the power supply as its source input, the NMOS transistor MN2 as a switching element, and an NMOS transistor MN5 as a restriction element for restricting the charging target voltage based on the constant current outputted from the constant current supply, are connected, thereby constituting a second delay circuit having the gate input of the NMOS transistor MN2 as its input and the node A1 connecting the source of the NMOS transistor MN5 and the drain of the NMOS transistor MN2 as its output. Further, the PMOS transistor MP3 as a constant current supply, the NMOS transistor MN3 as a switching element, and an NMOS transistor MN6 as a restriction circuit are connected in like manner, thereby constituting a third delay circuit having the gate input of the NMOS transistor MN3 as its input, and the node A3 connecting the source of the NMOS transistor MN6 and the drain of the NMOS transistor MN3 as its output.

Then, the first to third delay circuits are cascade-connected so that the output A1 of the first delay circuit is connected to the input of the second delay circuit, the output A2 of the second delay circuit is connected to the input of the third delay circuit, and the output A3 of the third delay circuit is connected to the input of the first delay circuit.

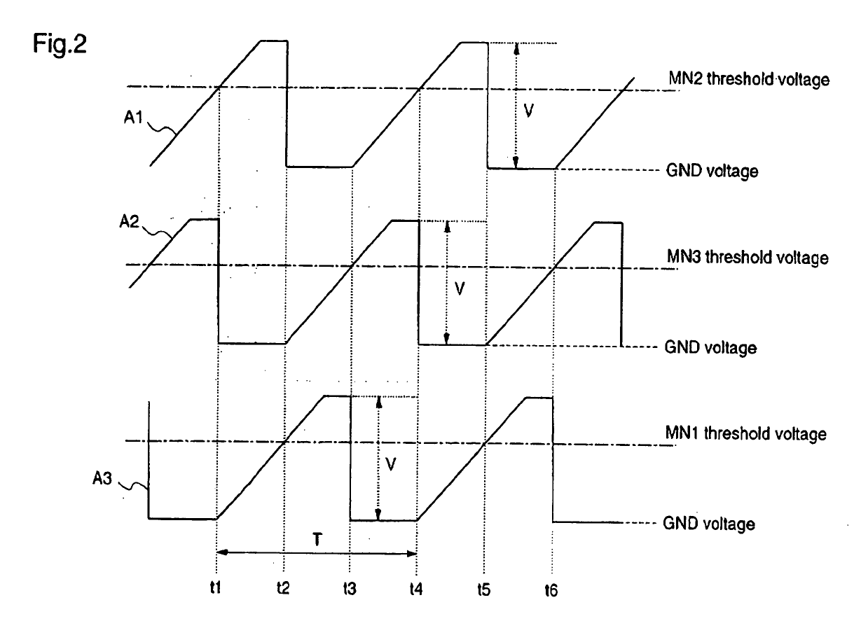

Hereinafter, the operation of the oscillation circuit constructed as described above will be described with reference to timing charts shown in FIG. 2. FIG. 2 shows operation timing charts at the nodes A1, A2, and A3 of the oscillation circuit according to the first embodiment. In FIG. 2, alternate long and short dashed lines indicate the threshold voltages of the NMOS transistors MN1, MN2, and MN3.

Initially, the PMOS transistor MP1, MP2, and MP3 as constant current supplies pass a constant current according to the voltage supplied from the current control terminal 2. In the following description, for simplification, it is assumed that the oscillation circuit is in its ideal state where the time required for the respective nodes A1, A2, and A3 to change to the threshold voltages of the NMOS transistors MN1, MN2, and MN3 after the NMOS transistors MN1, NM2, and NM3 as switching elements are turned on.

As shown in FIG. 2, since, at time t1, the voltage at the node A1 exceeds the threshold voltage of tho NMOS transistor MN2, the NMOS transistor MN2 is turned on, and the voltage at the node A2 becomes equal to or lower than the threshold voltage at the turn-on of the NMOS transistor NM2. Then, the NMOS transistor MN3 is turned off when the voltage at the node A2 becomes equal to or lower than the threshold voltage, and charging of the node A3 by the constant current outputted from the PMOS transistor MP3 is started.

During a period from t2 to t3, the node A3 is charged by the constant current outputted from the PMOS transistor MP3 continuously from the previous period (t1 to t2). Since, at time t2 that is the starting point of this period, the voltage at the node A3 exceeds the threshold voltage of the NMOS transistor MN1, the NMOS transistor MN1 is turned on, and the node A1 becomes equal to or lower than the threshold voltage at the turn-on of the NMOS transistor MN1. When the voltage at the node A1 becomes equal to or lower than the threshold voltage, the NMOS transistor MN2 is turned off, and charging of the node A2 by the constant current outputted from the PMOS transistor MP2 is started.

During a period from t3 to t4, the node A2 is charged by the constant current outputted from the PMOS transistor MP2 continuously from the previous period (t2 to t3). Since, at time t3 that is the starting point of this period, the voltage at the node A2 exceeds the threshold voltage of the NMOS transistor MN3, the NMOS transistor MN3 is turned on, and the voltage at the node A3 becomes equal to or lower than the threshold voltage at the turn-on of the NMOS transistor MN3. When the voltage at the node A3 becomes equal to or lower than the threshold voltage, the NMOS transistor MN1 is turned off, and charging of the node A1 by the constant current outputted from the PMOS transistor MP1 is started.

Thereafter, by repeating the operation performed from t1 to t4, the oscillation circuit according to the first embodiment oscillates at a cycle T.

Accordingly, the oscillation cycle T is the total of the periods until the voltages at the respective nodes A1, A2, and A3 are charged up to the threshold voltage of the NMOS transistors MN1, MN2, and MN3 by the constant current that is outputted from the PMOS transistors MP1, MP2, and MP3 according to the voltage inputted to the current control terminal 2.

Accordingly, in a series of oscillation operations described above, the voltage supplied from the current control terminal 2 is changed to change the constant current outputted from the PMOS transistors MP1, MP2, and MP3, thereby changing the lengths of the respective periods until the voltages at the nodes A1, A2, and A3 are charged up to the threshold voltage of the NMOS transistor MN1, MN2, and MN3, and thus the oscillation cycle T can be changed.

In FIG. 2, “V” indicates a charging target voltage to be attained by charging with the constant current supplied from the PMOS transistors MP1, MP2, and MP3, and the charging target voltage V is restricted to a voltage which is lower than the power supply voltage by the threshold voltage Vt of the NMOS transistors MN4, MN5, and MN6, by the NMOS transistors MN4, MN5, and MN6 which are restriction elements to which the power supply voltage is input at their gates. Since the voltage that is lower than the power supply voltage by the threshold voltage Vt is a constant voltage, the charging target voltage V restricted to this voltage becomes a constant voltage independent of the oscillation cycle T whether the oscillation cycle T is long or short.

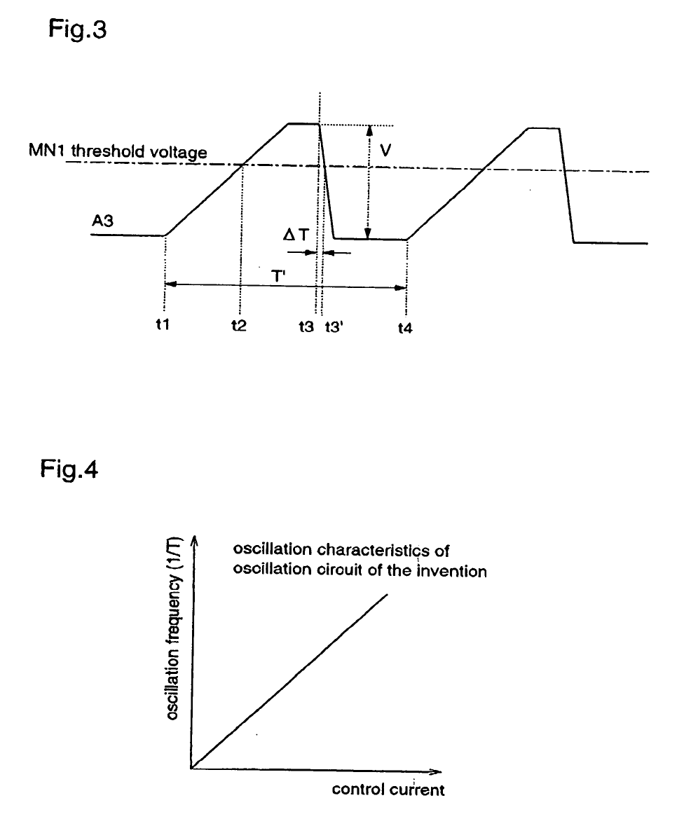

While the above description is given of the ideal state where the transition time required for the voltages at the respective nodes A1, A2, and A3 to change from the charging target voltage V to the threshold voltage is zero. However, actually the transition time is not zero but is as shown in FIG. 3. FIG. 3 is a diagram showing the operation timing chart of the node A3 when considering the transition time during which the voltages at the respective nodes A1, A2, and A3 change from the charging target voltage V to the threshold voltage. In FIG. 3, “ΔT” is the time required for the voltage at the node A3 to change from the charging target voltage V to the threshold voltage of the NMOS transistor MN1. That is, in the ideal state where the transition time is zero as shown in FIG. 2, the voltage of the node A3 becomes equal to or lower than the threshold voltage simultaneously with the turn-on of the NMOS transistor MN3 at time t3, and charging of the node A1 is started at time t3 by the constant current outputted from the PMOS transistor MP1. However, actually, as shown in FIG. 3, the NMOS transistor MN3 is turned on at time t3 and, after the transition time ΔT in which the voltage of the node A3 changes to the threshold voltage of the NMOS transistor MN1 has passed, charging of the node A1 is started at time t3′ by the constant current outputted from the PMOS transistor MP1.

Therefore, the actual oscillation cycle T′ is expressed by T′=(period from t1 to t2+ΔT)+(period from t2 to t3+ΔT)+(period from t3 to t4+ΔT)

In contrast to the ideal oscillation cycle T obtained without considering the transition time ΔT during which the respective nodes A1 to A3 change from the charging target voltage V to the threshold voltage, the actual oscillation cycle T′ is

T′=T+3*ΔT

In the conventional oscillation circuit, since the charging target voltage V changes depending on the oscillation cycle, the transition time ΔT also changes depending on the oscillation cycle. However, in the oscillation circuit of the first embodiment, the charging target voltage V does not depend on the oscillation cycle but becomes a constant voltage that is lower than the power supply voltage by the threshold voltage Vt of the NMOS transistors MN4, MN5, and MN6, and therefore, the transition time ΔT also becomes constant.

Accordingly, in this first embodiment, even when the oscillation cycle is obtained considering the transition time ΔT, since the transition time ΔT is constant regardless of the oscillation cycle, the oscillation characteristics of the oscillation circuit of the first embodiment considering the transition time ΔT are not degraded in contrast to the oscillation characteristics of the conventional circuit shown in FIG. 17 in which the linearity of the oscillation frequency against the constant current is degraded. That is, in this first embodiment, the linearity of the oscillation frequency against the constant current can be maintained as shown in FIG. 4.

As described above, according to the first embodiment, since the NMOS transistors MN4, MN5, and MN6 whose gate inputs are fixed to the power supply are inserted at the nodes A1, A2, and A3 connecting the PMOS transistors MP1, MP2, and MP3 as constant current supplies of the oscillation circuit and the NMOS transistors MN1, MN2, and MN3 as switching elements, respectively, the charging target voltage V of the nodes A1, A2, and A3 can be made constant regardless of the oscillation cycle T by restricting the possible upper-limit voltage of the nodes A1, A2, and A3 to a voltage that is lower than the power supply voltage by the threshold voltage Vt of the NMOS transistors MN4, MN5, and MN6. Therefore, the transition time ΔT during which the voltages at the node A1, A2, and A3 change from the charging target voltage V to the threshold voltage of the NMOS transistors MN1, MN2, and MN3 can be made constant. As a result, the linearity of the oscillation frequency to the constant current outputted from the PMOS transistors MP1, MP2, and MP3 as constant current supplies can be improved.

While in this first embodiment the gate inputs of the NMOS transistors MN4, MN5, and MN6 are the power supply voltage, the gate inputs may be an arbitrary constant voltage In this case, the possible upper-limit voltage at the nodes A1, A2, and A3 is restricted to a voltage that is lower than the arbitrary constant voltage by the threshold voltage Tv of the NMOS transistors MN4, MN5, and MN6.

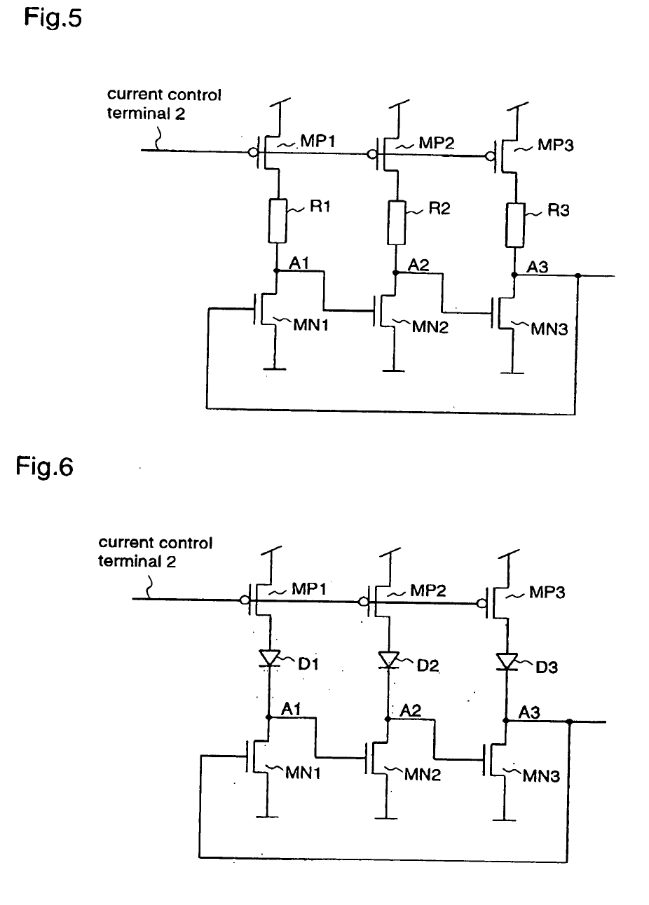

Further, in this first embodiment, the restriction elements for restricting the charging target voltage V of the respective nodes A1, A2, and A3 so as to be constant regardless of the oscillation cycle of the oscillation circuit are the NMOS transistors MN4, MN5, and MN6 whose gate inputs are the power supply voltage or an arbitrary constant voltage, the restriction elements are not limited to the NMOS transistors. Any element may be used as long as it can restrict the charging target voltage V of the nodes A1, A2, and A3 to a constant value regardless of the oscillation frequency of the oscillation circuit. For example, resistors or diodes may be employed. FIGS. 5 and 6 are diagrams illustrating other constructions of oscillation circuits according to the first embodiment. As the restriction elements for restricting the charging target voltage V of the respective nodes A1, A2, and A3, resistors R1 to R3 are provided in FIG. 5 while diodes D1 to D3 are provided in FIG. 6, at the drain sides of the PMOS transistors MP1, MP2, and MP3 as the constant current supply, respectively. The operations of the oscillation circuits shown in FIGS. 5 and 6 are identical to that of the oscillation circuit shown in FIG. 1, and therefore, repeated description is not necessary.

[Embodiment 2]

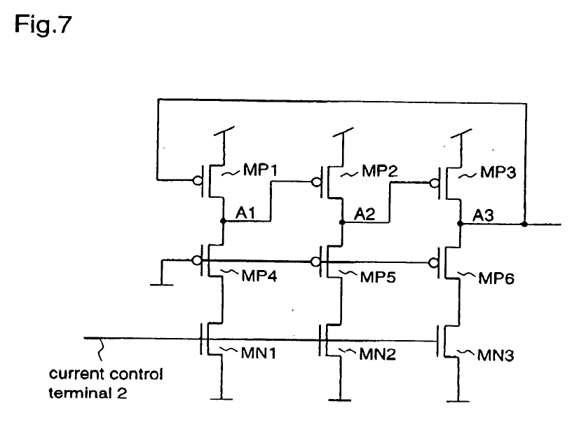

Hereinafter, a second embodiment of the present invention will be described with reference to FIGS. 7 to 9.

In the oscillation circuit according to the first embodiment, the constant current supply for outputting the constant current according to the voltage supplied from the control current terminal comprises the PMOS transistors MP1, MP2, and MP3, and the constant current is changed to change the length of the period during which the switching element comprising the NMOS transistors MN1, MN2, and MN3 is charged up to the threshold voltage, thereby changing the oscillation cycle T of the oscillation circuit. In the oscillation circuit according to this second embodiment, however, the constant current supply comprises MNOS transistors while the switching element comprises PMOS transistors, and the magnitude of the constant current outputted from the constant current supplies is changed to change the length of a period during which the switching elements are discharged to a threshold voltage, thereby changing the oscillation cycle T of the oscillation circuit.

Initially, the construction of the oscillation circuit according to the second embodiment will be described with reference to FIG. 7.

As shown in FIG. 7, the oscillation circuit of the second embodiment is constituted by the constant current supplies comprising NMOS transistors that are controlled by a voltage inputted to the current control terminal 2, and switching elements comprising PMOS transistors that are discharged by a constant current outputted from the constant current supplies, and are turned on when exceeding a threshold voltage, and the length of a period during which the switching elements are discharged to the threshold voltage is changed by changing the voltage supplied from the current control terminal 2, thereby changing the oscillation cycle T of the oscillation circuit. In this second embodiment, restriction elements for restricting the discharging target voltage based on the constant current outputted from the constant current supply to a constant value regardless of the oscillation cycle are provided between the constant current supplies and the switching elements.

Hereinafter, the construction of the oscillation circuit will be described in detail. In the oscillation circuit of this second embodiment, the drain of the NMOS transistor MN1 which is a constant current supply having the current control terminal 2 as its gate input and the GND as its source input is connected to the drain of the PMOS transistor MP4 as a restriction element, the gate input of the PMOS transistor MP4 is connected to the GND, the source of the PMOS transistor MP4 and the drain of the PMOS transistor MP1 as a switching element are connected at a node A1, and the source of the PMOS transistor MP1 is connected to the power supply, thereby constituting a first delay circuit having the gate input of the PMOS transistor MP1 as its input and the node A1 as its output. Likewise, the NMOS transistor MN2 that is a constant current supply having the current control terminal 2 as its gate input and the power supply as its source input, the PMOS transistor MP2 as a switching element, and the PMOS transistor MP5 as a restriction circuit for restricting the discharging target voltage based on the constant current outputted from the constant current supply, are connected, thereby constituting a second delay circuit having the gate input of the PMOS transistor MP2 as its input and the node A2 connecting the source of the PMOS transistor MP5 and the drain of the PMOS transistor MP2 as its output. Further, the NMOS transistor MN3 as a constant current supply, the PMOS transistor MP6 as a restriction element, and the PMOS transistor MP3 as a switching element are connected in like manner, thereby constituting a third delay circuit having the gate input of the NMOS transistor MN3 as its input, and the node A3 connecting the source of the NMOS transistor MN6 and the drain of the NMOS transistor MN3 as its output.

Then, the first to third delay circuits are cascade-connected so that the output A1 of the first delay circuit is connected to the input of the second delay circuit, the output A2 of the second delay circuit is connected to the input of the third delay circuit, and the output A3 of the third delay circuit is connected to the input of the first delay circuit.

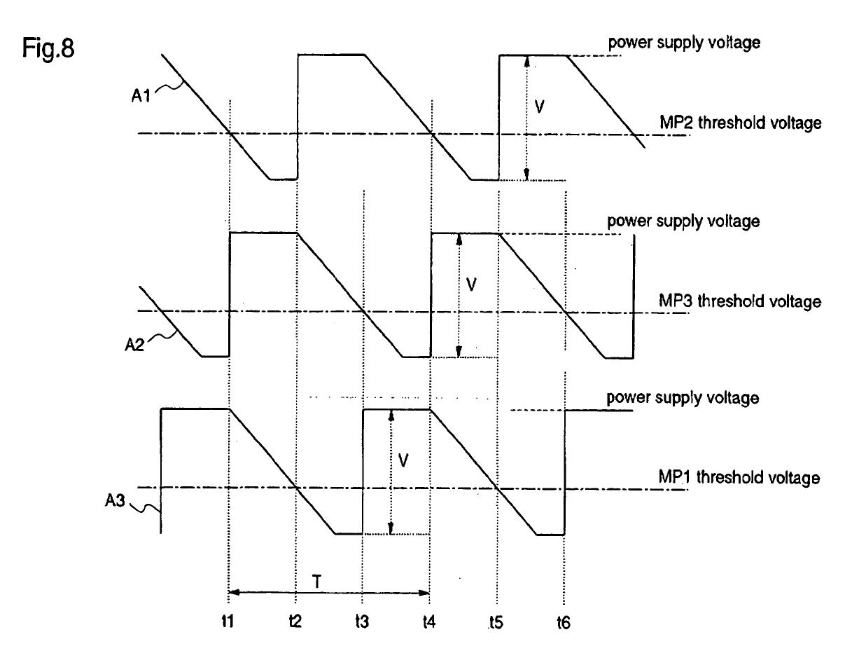

Hereinafter, the operation of the oscillation circuit constructed as described above will be described with reference to timing charts shown in FIG. 8. FIG. 8 shows operation timing charts at the nodes A1, A2, and A3 of the oscillation circuit according to the first embodiment. In FIG. 2, alternate long and short dashed lines indicate the threshold voltage of the PMOS transistors MP1, MP2, and MP3.

Initially, the NMOS transistors MN1, MN2, and MP3 as constant current supplies pass a constant current according to the voltage supplied from the current control terminal 2. In the following description, for simplification, it is assumed that the oscillation circuit is in its ideal state where the time required for the voltages at the respective nodes A1, A2, and A3 to change to the threshold voltage of the PMOS transistors MP1, MP2, and MP3 after the PMOS transistors MP1, NP2, and NP3 as switching elements are turned on.

As shown in FIG. 8, since, at time t1, the voltage at the node A1 becomes equal to or lower than the threshold voltage of the PMOS transistor MP2, the PMOS transistor MP2 is turned on, and the voltage of the node A2 becomes equal to or larger than the threshold voltage at the turn-on of the PMOS transistor MP2. Then, the PMOS transistor MP3 is turned off when the voltage of the node A2 becomes equal to or larger than the threshold voltage, and discharging of the node A3 is started by the constant current outputted from the NMOS transistor MN3.

During a period from t2 to t3, the node A3 is discharged by the constant current outputted from the NMOS transistor MN3 continuously from the previous period (t1 to t2). Since, at time t2 that is the starting point of this period, the voltage at the node A3 becomes equal to or lower than the threshold voltage of the PMOS transistor MP1, the PMOS transistor MP1 is turned on, and the node A1 becomes equal to or larger than the threshold voltage at the turn-on of the PMOS transistor MP1. Then, the PMOS transistor MP2 is turned off when the voltage of the node A1 becomes equal to or larger than the threshold voltage, and discharging of the node A2 is started by the constant current outputted from the NMOS transistor MN2.

During a period from t3 to t4, the node A2 is discharged by the constant current outputted from the NMOS transistor MN2 continuously from the previous period (t2 to t3). Since, at time t3 that is the starting point of this period, the voltage of the node A2 becomes equal to or lower than the threshold voltage of the PMOS transistor MP3, the PMOS transistor MP3 is turned on, and the PMOS transistor MP1 is turned off when the voltage of the node A3 becomes equal to or larger than the threshold voltage, and discharging of the node A1 is started by the constant current outputted from the NMOS transistor MN1.

Thereafter, by repeating the operation from t1 to t4, the oscillation circuit according to the second embodiment oscillates at a cycle T.

Accordingly, the oscillation cycle T is the total of the periods required until the voltages at the respective nodes A1, A2, and A3 are discharged to the threshold voltage of the PMOS transistors MP1, MP2, and MP3 by the constant current that is outputted from the NMOS transistors MN1, MN2, and MN3 according to the voltage inputted to the current control terminal 2.

Accordingly, in a series of oscillation operations described above, the voltage supplied from the current control terminal 2 is changed to change the constant current outputted from the NMOS transistors MN1, MN2, and MN3, thereby changing the lengths of the respective periods required until the voltages at the nodes A1, A2, and A3 are discharged from the power supply voltage to the threshold voltage of the PMOS transistors MP1, MP2, and MP3, and thus the oscillation cycle T can be changed.

In FIG. 8, “V” indicates a discharging target voltage to be attained by discharging with the constant current outputted from the NMOS transistors MN1, MN2, and MN3, and the discharging target voltage V is restricted to a voltage which is higher than the GND voltage by the threshold voltage Vt of the PMOS transistors MP4, MP5, and MP6, by the PMOS transistors MP4, MP5, and MP6 to which the GND voltage is input at their gates. Since the voltage that is higher than the GND voltage by the threshold voltage Vt is a constant voltage, the discharging target voltage V restricted to this voltage is a constant voltage that is independent of the oscillation cycle T whether the oscillation cycle T is long or short.

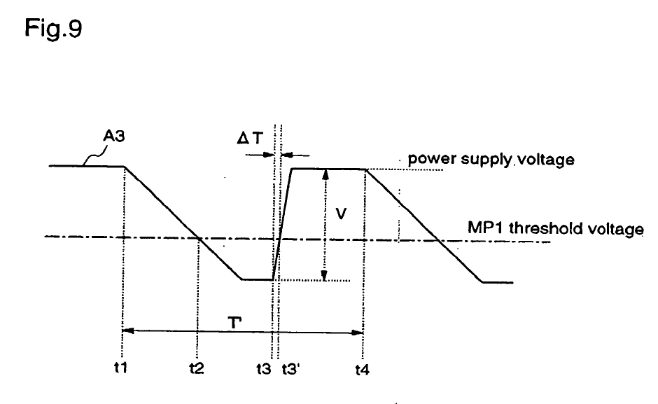

While the above description is given of the ideal state where the transition times required for the voltages at the respective nodes A1, A2, and A3 to change from the discharging target voltage V to the threshold voltage is zero. However, the transition time is actually not zero but is as shown in FIG. 9. FIG. 9 is a diagram showing the operation timing chart of the node A3 when considering the transition time during which the voltages of the respective nodes A1, A2, and A3 change from the discharging target voltage V to the threshold voltage. In FIG. 9, “ΔT” is the time required for the voltage at the node A3 to change from the discharging target voltage V to the threshold voltage of the PMOS transistor MP1. That is, in the ideal state where the transition time is zero as shown in FIG. 7, the voltage of the node A3 becomes equal to or higher than the threshold voltage simultaneously with the turn-on of the PMOS transistor MP3 at time t3, and discharging of the node A1 is started at time t3 by the constant current outputted from the NMOS transistor MN1. However, actually, as shown in FIG. 9, the PMOS transistor MP3 is turned on at time t3, and after the transition time ΔT during which the voltage of the node A3 changes to the threshold voltage of the PMOS transistor MP1 has passed, discharging of the node A1 is started at time t3′ by the constant current outputted from the NMOS transistor MN1.

Therefore, the actual oscillation cycle T′ is expressed by T′=(period from t1 to t2+ΔT)+(period from t2 to t3+ΔT)+(period from t3 to t4+ΔT)

In contrast to the ideal oscillation cycle T obtained without considering the transition time ΔT during which the respective nodes A1 to A3 change from the discharging target voltage V to the threshold voltage, the actual oscillation cycle T′ is

T′=T+3*ΔT

In the conventional oscillation circuit, since the charging target voltage V changes depending on the oscillation cycle, the transition time ΔT also changes depending on the oscillation cycle However, in the oscillation circuit of the second embodiment, the discharging target voltage V does not depend on the oscillation cycle T but becomes a constant voltage that is higher than the GND by the threshold voltage Vt of the PMOS transistors MP4, MP5, and MP6 than the GND voltage, and therefore, the transition time ΔT also becomes constant.

Since the discharging target voltage V varies depending on the oscillation cycle T in the conventional oscillation circuit, and the transition time ΔT also varies depending on the oscillation cycle T. In this second embodiment, however, since the discharging target voltage V is a constant voltage regardless of the oscillation cycle T, the transition time ΔT also becomes constant.

Accordingly, in this second embodiment, even when the oscillation cycle is obtained considering the transition time ΔT, since the transition time ΔT is constant regardless of the oscillation cycle, the oscillation characteristics of the oscillation circuit of this second embodiment considering the transition time ΔT are not degraded in contrast to the oscillation characteristics of the conventional circuit shown in FIG. 17 in which the linearity of the oscillation frequency against the constant current is degraded. That is, in this second embodiment, the linearity of the oscillation frequency against the constant current can be maintained.

As described above, according to the second embodiment, since the PMOS transistors MP4, MP5, and MP6 whose gate inputs are fixed to the GND are inserted to the nodes A1, A2, and A3 connecting the NMOS transistors MN1, MN2, and MN3 as constant current supplies of the oscillation circuit and the PMOS transistors MP1, MP2, and MP3 as a switching element, respectively, the discharging target voltage V of the nodes A1, A2, and A3 can be made constant regardless of the oscillation cycle T by restricting the possible upper-limit voltage of the nodes A1, A2, and A3 to a voltage that is higher than the GND by the threshold voltage Vt of the PMOS transistors MP4, MP5, and MP6. Therefore, the transition time ΔT in which the voltages of tile nodes A1, A2, and A3 change from the discharging target voltage V to the threshold voltage of the PMOS transistor MP1, MP2, and MP3 can be made constant. As a result, the linearity of the oscillation frequency against the constant current outputted from the NMOS transistors MN1, MN2, and MN3 as the constant current supply can be improved.

While in this second embodiment the gate inputs of the PMOS transistors MP4, MP5, and MP6 are the GND, the gate inputs may be an arbitrary constant voltage. In this case, the possible lower-limit voltage of the nodes A1, A2, and A3 is restricted to a voltage that is higher than the arbitrary constant voltage by the threshold voltage Vt of the PMOS transistors MP4, MP5, and MP6.

Further, in this second embodiment, the restriction elements for restricting the discharging target voltage V of the respective nodes A1, A2, and A3 so as to be a constant value regardless of the oscillation cycle of the oscillation circuit are the PMOS transistors MP4, MP5, and MP6 whose gate inputs are the GND or an arbitrary constant voltage, the restriction elements are not limited to the PMOS transistors, and any element may be used as long as the discharging target voltage V of the nodes A1, A2, and A3 is restricted to a constant value regardless of the oscillation frequency of the oscillation circuit. For example, resistors or diodes may be employed.

[Embodiment 3]

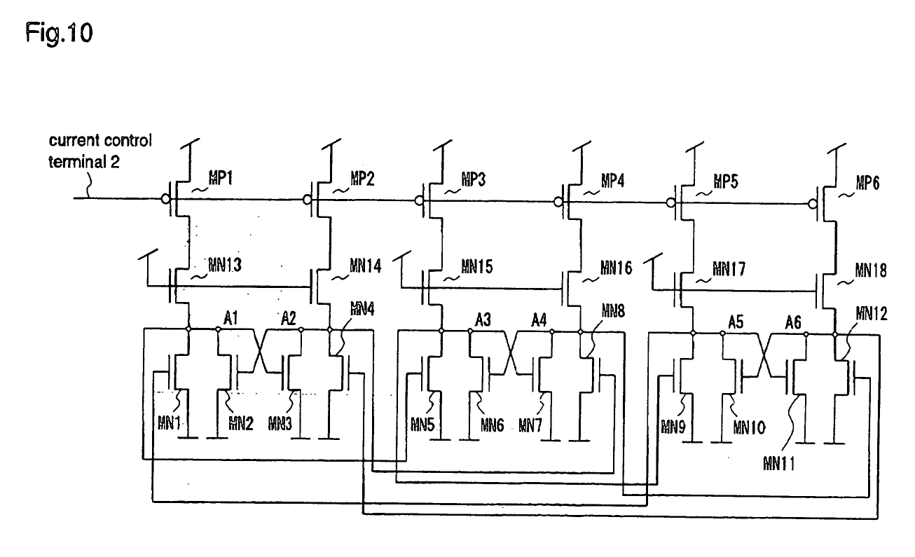

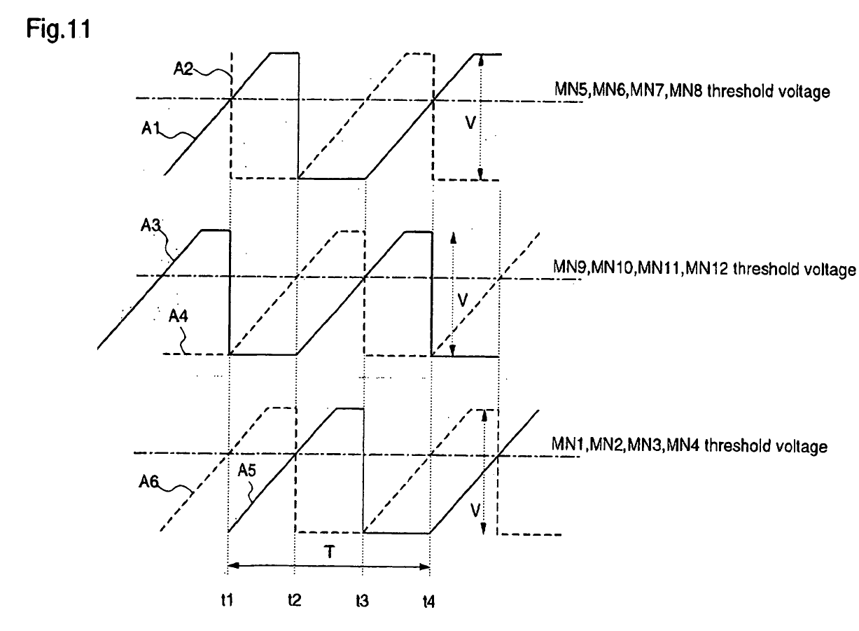

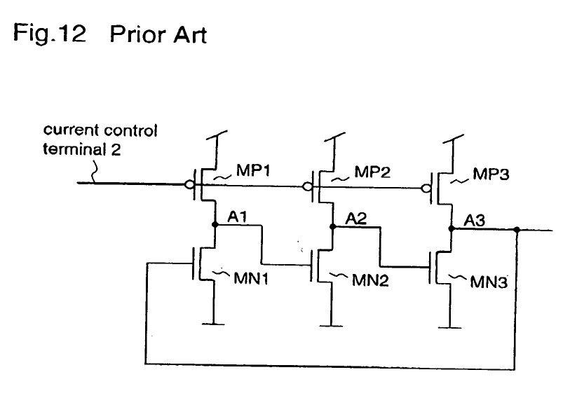

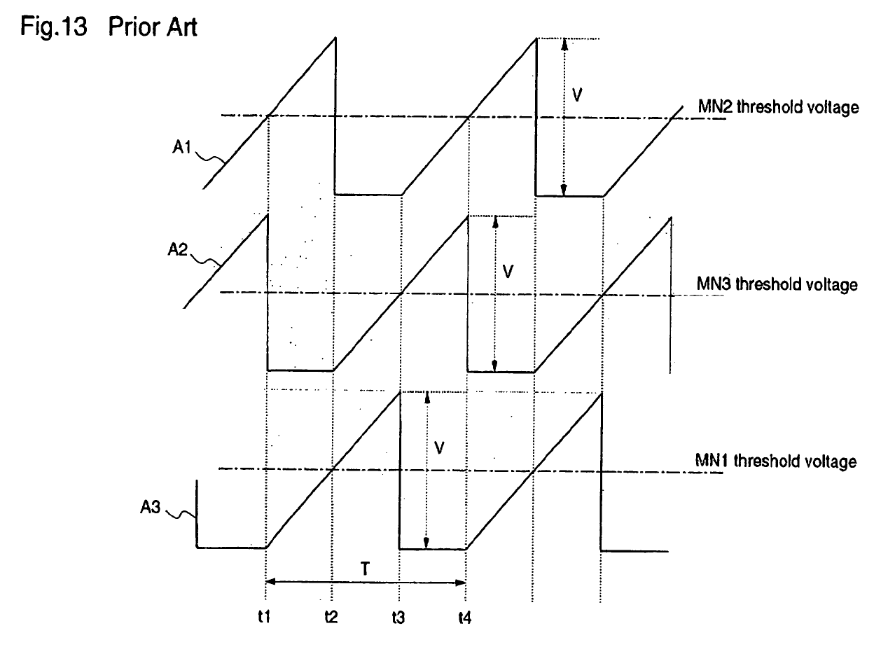

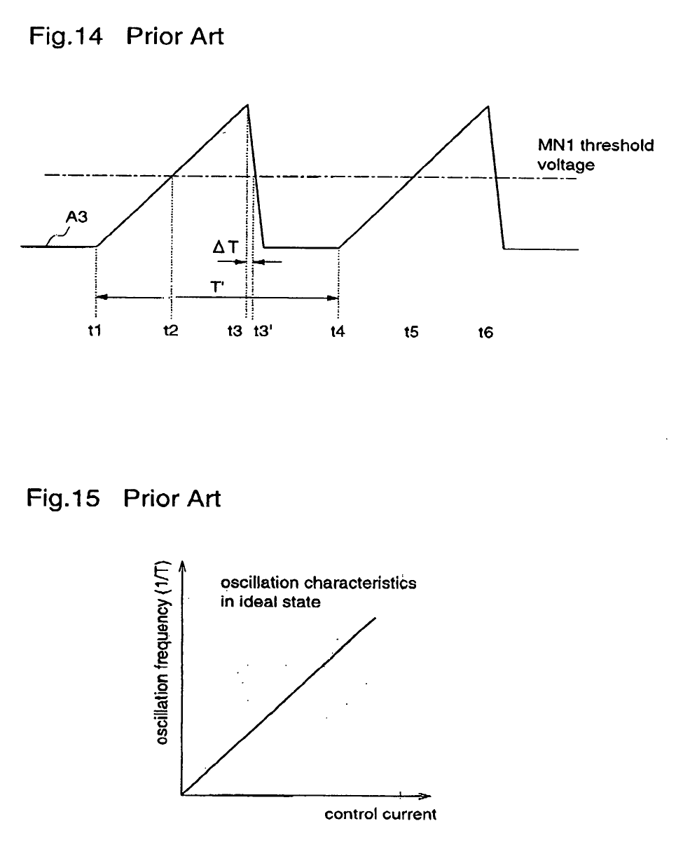

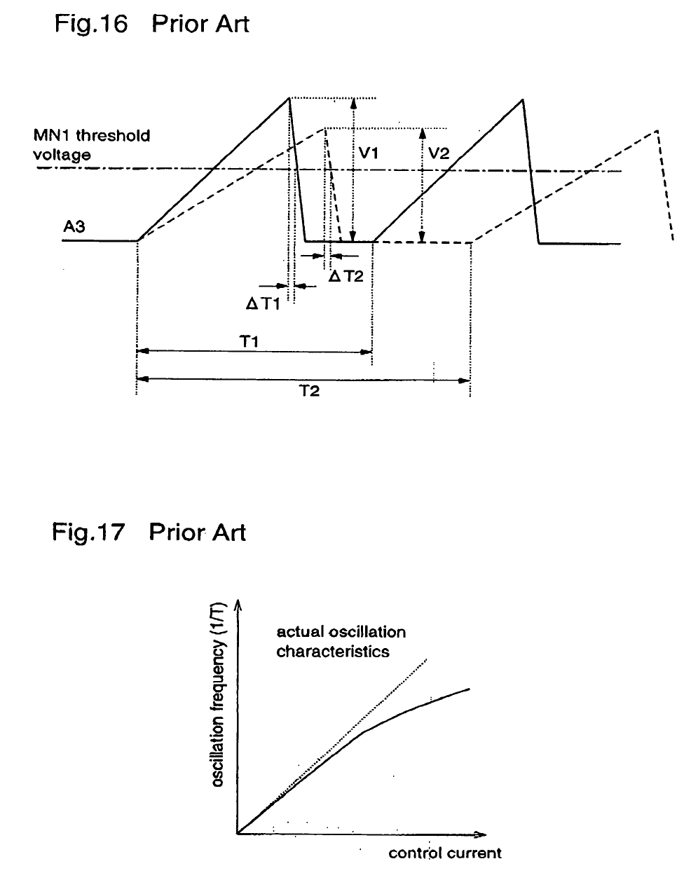

Hereinafter, a third embodiment of the present invention will be described with reference to FIGS. 10 and 11.

In the oscillation circuit according to the first embodiment, the constant current supply for outputting the constant current according to the voltage supplied from the control current terminal is composed of the PMOS transistors MP1, MP2, and MP3, and the magnitude of the constant current is changed to change the length of the period during which the switching element comprising the NMOS transistors MN1, MN2, and MN3 is charged up to the threshold voltage, thereby changing the oscillation cycle T of the oscillation circuit. In this third embodiment, however, the constant current supply comprises PMOS transistors while the switching element comprises differential circuit including NMOS transistors.

Initially, the construction of the oscillation circuit according to the third embodiment will be described with reference to FIG. 10.

As shown in FIG. 10, the oscillation circuit of this third embodiment comprises a constant current supply comprising PMOS transistors that are controlled by a voltage supplied from the current control terminal 2, and a switching element comprising differential circuits including NMOS transistors that are charged by the constant current supplied from the constant current supply and are turned on when exceeding a threshold voltage. The length of a period during which the switching element is charged lip to the threshold voltage is changed by changing the voltage supplied from the current control terminal 2, thereby changing the oscillation cycle of the oscillation circuit. A restriction element for restricting the charging target voltage by the constant current outputted from the constant current supply so as to be constant regardless of the oscillation cycle is provided between the constant current supply and the switching element.

Hereinafter, the construction of the oscillation circuit will be described in detail. In the oscillation circuit according to the third embodiment, between the PMOS transistor MP1 and the PMOS transistor MP2 each being a constant current supply having the current control terminal 2 as its gate input and the power supply as its source input, the drain of the PMOS transistor MP1 is connected to the drain of the NMOS transistor MN13 as a restriction element, the drain of the PMOS transistor MP2 is connected to the drain of the NMOS transistor MN14 as a restriction element, the gate inputs of the NMOS transistor MN13 and the NMOS transistor MN14 are connected to the power supply, the source of the NMOS transistor MN13 and the drains of the NMOS transistor MN1 and the NMOS transistor MN2 are connected at the node A1, the source of the NMOS transistor MN14 and the drains of the NMOS transistor MN4 and the NMOS transistor MN3 which are switching elements are connected at the node A2, and the sources of the NMOS transistors MN1, MN2, MN3, and MN4 are connected to the GND, thereby constituting a first delay circuit having the gate input of the NMOS transistor MN1 as its positive side input the gate input of the NMOS transistor MN4 as its negative side input, the node A1 as its negative side output, and the node A2 as its positive side output. Likewise, the PMOS transistors MP3 and MP4 each being a constant current supply having the current control terminal 2 as its gate input and the power supply as its source input, the NMOS transistors MN5, MN6, MN7, and MN8 having the construction of a differential circuit as a switching element, and the NMOS transistors MN15 and MN16 which are restriction elements for restricting the charging target voltage by the constant current outputted from the constant current supply, thereby constituting a second delay circuit having the gate input of the NMOS transistor MN5 as its positive side input, the gate input of the NMOS transistor MN8 as its negative side input, the node A3 as its negative side output, and the node A4 as its positive side output. Furthermore, the PMOS transistors MP5 and MP6 as constant current supplies, the NMOS transistors MN17 and MN18 as restriction elements, and the NMOS transistors MN9˜MN12 as switching elements are connected, thereby constituting a third delay circuit having the gate input of the NMOS transistor MN9 as its positive side input, the gate input of the NMOS transistor MN12 as its negative side input, the node A5 as its negative side output, and the node A6 as its positive side output.

The first to third delay circuits are cascade-connected such that the negative side output A1 of the first delay circuit is connected to the positive side input of the second delay circuit, the positive side output A2 of the first delay circuit is connected to the negative side input of the second delay circuit, the negative side output A3 of the second delay circuit is connected to the positive side input of the third delay circuit, the positive side output A4 of the second delay circuit is connected to the negative side input of the third delay circuit, the negative side output A5 of the third delay circuit is connected to the positive side input of the first delay circuit, and the positive side output A6 of the third delay circuit is connected to the negative side input of the first delay circuit.

The operation of the oscillation circuit according to the third embodiment constructed as described above will be described with reference to timing charts of FIG. 11. FIG. 11 shows operation timing charts at the nodes A1, A2, A3, A4, A5, and A6 in the oscillation circuit of the third embodiment. In FIG. 11, the alternate long and short dashed line indicates the threshold voltage of the NMOS transistors MN1, MN2, MN3, MN4, MN5, MN6, MN7, MN8, MN9, MN10, MN11, and MN12.

Initially, the PMOS transistors MP1, MP2, MP3, MP4, MP5, and MP6 as a constant current supply pass a constant current according to the voltage supplied from the current control terminal 2. In the following simplification, for simplification, it is assumed that the oscillation circuit is in its ideal state where the time required for the voltages of the respective nodes A1, A2, A3, A4, A5, and A6 to change to the threshold voltage of the NMOS transistors MN1, MN2, MN3, MN4, MN5, MN6, MN7, MM8, MN9, MN10, MN11, and MN12 after the respective NMOS transistors are turned on.

As shown in FIG. 11, at time t1, the voltage at the node A1 exceeds the threshold voltage of the NMOS transistor MN5, and the NMOS transistor MN5 is turned on, and the voltage at the node A3 becomes equal to or lower than the threshold voltage at the turn-on of the NMOS transistor NM5. Then, the NMOS transistor MN9 is turned off when the voltage at the node A3 becomes equal to or lower than the threshold voltage, and charging of the node A5 is started by the constant current outputted from the PMOS transistor MP5.

During a period from t2 to t3, the node A5 is charged by the constant current outputted from the PMOS transistor MP5 continuously from the previous period (t1 to t2). Since, at time t2 that is the starting point of this period, the voltage at the node A5 exceeds the threshold voltage of the NMOS transistor MN1, the NMOS transistor MN1 is turned on, and the node A1 becomes equal to or lower than the threshold voltage at the turn-on of the NMOS transistor MN1. When the voltage at the node A1 becomes equal to or lower than the threshold voltage, the NMOS transistor MN5 is turned off, and charging of the node A3 by the constant current outputted from the PMOS transistor MP2 is started.

During a period from t3 to t4, the node A3 is charged by the constant current outputted from the PMOS transistor MP3 continuously from the previous period (t2 to t3). Since, at time t3 that is the starting point of this period, the voltage at the node A3 exceeds the threshold voltage of the NMOS transistor MN9, the NMOS transistor MN9 is turned on, and the voltage at the node A5 becomes equal to or lower than the threshold voltage at the turn-on of the NMOS transistor MN9. When the voltage at the node. A5 becomes equal to or lower than the threshold voltage, the NMOS transistor MN1 is turned off, and charging of the node A1 is started by the constant current outputted from the PMOS transistor MP1.

Further, since the voltage at the node A6 exceeds the threshold voltage at time t1, the NMOS transistor MN4 is turned on, and the voltage at the node A2 becomes equal to or lower than the threshold voltage at the turn-on of the NMOS transistor MN4. The NMOS transistor MN4 is turned off when the voltage at the node A2 becomes equal to or lower than the threshold voltage, and charging of the node A4 by the constant current outputted from the PMOS transistor MP4 is started.

During the period from t2 to t3, the node A4 is charged by the constant current outputted from the PMOS transistor MP4 continuously from the previous period (t1 to t2). Since, at time t2 that is the starting point of this period, the voltage at the node A4 exceeds the threshold voltage of the NMOS transistor MN12, the NMOS transistor MN12 is turned on, and the node A6 becomes equal to or lower than the threshold voltage at the turn-on of the NMOS transistor MN12. When the voltage at the node A6 becomes equal to or lower than the threshold voltage, the NMOS transistor MN4 is turned off, and charging of the node A2 by the constant current outputted from the PMOS transistor MP2 is started.

During the period from t3 to t4, the node A2 is charged by the constant current outputted from the PMOS transistor MP2 continuously from the previous period (t2 to t3). Since, at time t3 that is the starting point of this period, the voltage at the node A2 exceeds the threshold voltage of the NMOS transistor MN8, the NMOS transistor MN8 is turned on, and the NMOS transistor MN12 is turned off when the voltage at the node A4 becomes equal to or lower than the threshold voltage, and then charging of the node A6 is started by the constant current outputted from the PMOS transistor MP6.

When the voltages at the nodes which are input to the gates of the NMOS transistors MN2, MN3, MN6, MN7, MN10, and MN11 exceed the threshold voltage, the voltages at the nodes to which the drains of these NMOS transistors are connected become equal to or lower than the threshold voltage.

By repeating the operation from time t1 to time t4, the oscillation circuit according to the third embodiment oscillates at a cycle T.

Accordingly, the oscillation cycle T is the total of the periods required until the voltages at the respective nodes A1, A2, A3, A4, A5, and A6 are charged up to the threshold voltage of the NMOS transistors MN1, MN2, MN3, MN4, MN5, MN6, MN7, MN8, MN9, MN10, MN11, and MN12 by the constant current that is outputted from the PMOS transistors MP1, MP2, MP3, MP4, MP5, and MP6 according to the voltage inputted to the current control terminal 2.

Accordingly, in a series of oscillation operations described above, the voltage supplied from the current control terminal 2 is changed to change the constant current to be outputted from the PMOS transistors MP1, MP2, MP3, MP4, MP5, and MP6, thereby changing the lengths of the respective periods required until the voltages at the nodes A1, A2, A3, A4, A5, and A6 are charged up to the threshold voltage of the NMOS transistor MN1, MN2, MN3, MN4, MN5, MN6, MN7, MN8, MN9, MN10, MN11, and MN12, and thus the oscillation cycle T can be changed.

In FIG. 11, “V” indicates a charging target voltage to be attained by charging with the constant current outputted from the PMOS transistors MP1, MP2, MP3, MP4, MP5, and MP6, and the charging target voltage V is restricted to a voltage that is lower than the power supply voltage by the threshold voltage Vt of the NMOS transistors MN13, MN14, MN15, MN16, MN17, and MN18, by these NMOS transistors that are restriction elements to which the power supply voltage is input at their gates. Since the voltage that is lower than the power supply voltage by the threshold voltage Vt is a constant voltage, the charging target voltage V restricted to this voltage is a constant voltage that is independent of the oscillation cycle T whether the oscillation cycle T is long or short.

While the above description is given of the ideal state where the transition time required for each of the voltages of the respective nodes A1, A2, A3, A4, A5, and A6 to change from the charging target voltage V to the threshold voltage is zero. However, the transition time is actually not zero. Accordingly, in contrast to the ideal oscillation cycle T that is obtained without considering the transition time ΔT in which the respective nodes A1 to A3 change from the charging target voltage V to the threshold voltage, the actual oscillation cycle T′ is expressed by

T′=T+3*ΔT

In the conventional oscillation circuit, since the charging target voltage V changes depending on the oscillation cycle, the transition time ΔT also changes depending on the oscillation cycle. However, in this third embodiment, however, the charging target voltage V does not depend on the oscillation cycle but becomes a constant voltage that is lower than the power supply voltage by the threshold voltage Vt of the NMOS transistors MN13, MN14, MN15, MN16, MN17, and MN18, and therefore, the transition time ΔT also becomes constant.

Accordingly, in this third embodiment, even when the oscillation cycle is obtained considering the transition time ΔT, since the transition time ΔT is constant regardless of the oscillation cycle, the oscillation characteristic of the oscillation circuit of the third embodiment considering the transition time ΔT is not degraded in contrast to the oscillation characteristic of the conventional circuit shown in FIG. 17 in which the linearity of tho oscillation frequency against the constant current is degraded. That is, in this third embodiment, the linearity of the oscillation frequency against the constant current can be maintained as shown in FIG. 4.

As described above, according to the third embodiment of the invention, since the NMOS transistors MN13, MN14, MN15, MN16, MN17, and MN18 whose gate inputs are fixed to the power supply are inserted to the nodes A1, A2, A3, A4, A5, and A6 connecting the PMOS transistors MP1, MP2, MP3, MP4, MP5, and MP6 as the constant current supplies of the oscillation circuit and the NMOS transistors MN1, MN2, MN3, MN4, MN5, MN6, MN7, MN8, MN9, MN10, MN11, and MN12 as the switching elements, respectively, the charging target voltage V of the nodes A1, A2, A3, A4, A5, and A6 can be made constant regardless of the oscillation cycle T by restricting the possible upper-limit voltage of the nodes A1, A2, A3, A4, A5, and A6 to a voltage that is lower than the power supply voltage by the threshold voltage Vt of the NMOS transistors MN13, MN14, MN15, MN16, MN17, and MN18. Therefore, the transition time ΔT in which the voltage at each of the node A1, A2, A3, A4, A5, and A6 changes from the charging target voltage V to the threshold voltage of the NMOS transistor MN13, MN14, MN15, MN16, MN17, and MN18 can be made constant. As a result, the linearity of the oscillation frequency to the constant current outputted from the PMOS transistors Me1, MP2, MP3, MP4, MP5, and MP6 as the constant current supplies can be improved.

While in this third embodiment the gate inputs of the NMOS transistors MN13, MN14, MN15, MN16, MN17, and MN18 are the power supply voltage, the gate inputs may be an arbitrary constant voltage. In this case, the possible upper-limit voltage of the nodes A1, A2, A3, A4, A5, and A6 is restricted to a voltage that is lower than the arbitrary constant voltage by the threshold voltage Vt of the NMOS transistors MN13, MN14, MN15, MN16, MN17, and MN18.

Further, in this third embodiment, the restriction elements for restricting the charging target voltage V of the respective nodes A1, A2, A3, A4, A5, and A6 so as to be a constant value regardless of the oscillation cycle of the oscillation circuit are the NMOS transistors MN13, MN14, MN15, MN16, MN17, and MN18 whose gate inputs are the power supply voltage or the arbitrary constant voltage, the restriction elements are not limited to the above-mentioned NMOS transistors. Any element may be used as long as it can restrict the charging target voltage V of the nodes A1, A2, A3, A4, A5, and A6 to a constant value regardless of the oscillation frequency of the oscillation circuit. For example, resistors or diodes may be employed.

Furthermore, while in the first to third embodiments, an oscillation circuit in which three stages of delay circuits are cascade-connected is taken as an example, an oscillation circuit in which N (N: integer equal to or larger than 2) stages of delay circuits is also in the scope of the present invention.

What is claimed is:

1. An oscillation circuit comprising a plurality of constant current supplies for outputting a constant current according to a voltage supplied from a control current terminal, and a plurality of switching elements which are charged or discharged by the constant current outputted from the constant current supplies and are turned on or off when exceeding a predetermined threshold voltage, wherein the voltage from the control current terminal is changed to change a time required until the switching elements are charged or discharged to the threshold voltage, thereby changing an oscillation cycle, said oscillation circuit further including:
restriction elements for restricting a charging target voltage or a discharging target voltage at nodes between the constant current supplies and the switching elements to a constant value.

2. An oscillation circuit as defined in claim 1, wherein the restriction elements comprise NMOS transistors or PMOS transistors.

3. An oscillation circuit as defined in claim 1, wherein the restriction elements comprise at least one resistor.

4. An oscillation circuit comprising:
a first delay circuit in which a drain of a PMOS transistor MP having a current control terminal as its gate input and a power supply as its source input is connected to a drain of an NMOS transistor MN4, a gate input of the NMOS transistor MN4 is connected to the power supply, a source of the NMOS transistor MN4 and a drain of the NMOS transistor MN1 are connected at a node A1, and a source of the NMOS transistor MN1 is connected to a GND, said first delay circuit having a gate input of the NMOS transistor MN1 as its input and the node A1 as its output;
a second delay circuit in which a drain of a PMOS transistor MP2 having the current control terminal as its gate input and the power supply as its source input is connected to a drain of an NMOS transistor MN5, a gate input of the NMOS transistor MN5 is connected to the power supply, a source of the NMOS transistor MN5 and a drain of the NMOS transistor MN2 are connected at a node A2, and a source of the NMOS transistor MN2 is connected to a GND, said second delay circuit having a gate input of the NMOS transistor MN2 as its input and the node A2 as its output;
a third delay circuit in which a drain of a PMOS transistor MN3 having the current control terminal as its gate input and the power supply as its source input is connected to a drain of an NMOS transistor MN6, a gate input of the NMOS transistor MN6 is connected to the power supply, a source of the NMOS transistor MN6 and the drain of the NMOS transistor MN3 are connected at a node A3, and a source of the NMOS transistor MN3 is connected to a GND, said third delay circuit having a gate input of the NMOS transistor MN3 as its input and the node A3 as its output; and
said first to third delay circuits being cascade-connected so that the output A1 of the first delay circuit is connected to the input of the second delay circuit, the output A2 of the second delay circuit is connected to the input of the third delay circuit, and the output A3 of the third delay circuit is connected to the input of the first delay circuit.

5. An oscillation circuit as defined in claim 4, wherein the gate inputs of the NMOS transistors MN4, MN5, and MN6 are fixed to an arbitrary constant voltage.

6. An oscillation circuit comprising:
a first delay circuit in which a drain of an NMOS transistor MN1 having a current control terminal as its gate input and a GND as its source input is connected to a drain of a PMOS transistor MP4, a gate input of the PMOS transistor MP4 is connected to the GND, a source of the PMOS transistor MP4 and a drain of the PMOS transistor MP1 are connected at a node A1, and a source of the PMOS transistor MP1 is connected to a power supply, said first delay circuit having a gate input of the PMOS transistor MP1 as its input and the node A1 as its output;
a second delay circuit in which a drain of an NMOS transistor MN2 having the current control terminal as its gate input and the GND as its source input is connected to a drain of a PMOS transistor MP5, a gate input of the PMOS transistor MP5 is connected to the GND, a source of the PMOS transistor MP5 and a drain of the PMOS transistor MP2 are connected at a node A2, and a source of the PMOS transistor MP2 is connected to a power supply, said second delay circuit having a gate input of the PMOS transistor MP2 as its input and the node A2 as its output;
a third delay circuit in which a drain of an NMOS transistor MN3 having the current control terminal as its gate input and the GND as its source input is connected to a drain of a PMOS transistor MP6, a gate input of the PMOS transistor MP6 is connected to the GND, a source of the PMOS transistor MP6 and the drain of the PMOS transistor MP3 are connected at a node A3, and a source of the PMOS transistor MP3 is connected to a power supply, said third delay circuit having a gate input of the PMOS transistor MP3 as its input and the node A3 as its output; and
said first to third delay circuits being cascade-connected so that the output A1 of the first delay circuit is connected to the input of the second delay circuit, the output A2 of the second delay circuit is connected to the input of the third delay circuit, and the output A3 of the third delay circuit is connected to the input of the first delay circuit.

7. An oscillation circuit as defined in claim 6, wherein the gate inputs of the PMOS transistors MP4, MP5, and MP6 are an arbitrary constant voltage.

8. An oscillation circuit comprising:
a first delay circuit in which a drain of a PMOS transistor MP1 having a current control terminal as its gate input and a power supply as its source input is connected to a drain of an NMOS transistor MN13, a drain of a PMOS transistor MP2 having the current control terminal as its gate input and the power supply as its source input is connected to a drain of an NMOS transistor MN14, gate inputs of the NMOS transistors MN13 and MN14 are connected to the power supply, a source of the NMOS transistor MN13 and drains of NMOS transistors MN1 and MN2 are connected at a node A1, and a source of the NMOS transistor MN14 and drains of NMOS transistor MN4 and MN3 are connected at a node A2, and the sources of the NMOS transistors MN1, MN2, MN3, and MN4 are connected to a GND, said first delay circuit having a gate input of the NMOS transistor MN1 as its positive side input, the gate input of the NMOS transistor MN4 as its negative side input, the node A1 as its negative side output, and the node A2 as its positive side output;
a second delay circuit in which a drain of a PMOS transistor MP3 having the current control terminal as its gate input and the power supply as its source input is connected to a drain of an NMOS transistor MN15, a drain of a PMOS transistor MP4 having the current control terminal as its gate input and the power supply as its source input is connected to a drain of an NMOS transistor MN16, gate inputs of the NMOS transistors MN15 and MN16 are connected to the power supply, a source of the NMOS transistor MN15 and drains of NMOS transistors MN5 and MN6 are connected at a node A3, a source of the NMOS transistor MN16 and drains of NMOS transistor MN7 and MN8 are connected at a node A4, and the sources of the NMOS transistors MN5, MN6, MN7, and MN8 are connected to a GND, said second delay circuit having the gate input of the NMOS transistor MN5 as its positive side input, the gate input of the NMOS transistor MN8 as its negative side input, the node A3 as its negative side output, and the node A4 as its positive side output;
a third delay circuit in which a drain of a PMOS transistor MP5 having the current control terminal as its gate input and the power supply as its source input is connected to a drain of an NMOS transistor MN17, a drain of a PMOS transistor MP6 having the current control terminal as its gate input and the power supply as its source input is connected to a drain of an NMOS transistor MN18, gate inputs of the NMOS transistors MN17 and MN18 are connected to the power supply, a source of the NMOS transistor MN17 and drains of NMOS transistors MN9 and MN10 are connected at a node A5, a source of the NMOS transistor MN18 and drains of NMOS transistor MN11 and MN12 are connected at a node A6, and the sources of the NMOS transistors MN9, MN10, MN11, and MN12 are connected to a GND, said third delay circuit having the gate input of the NMOS transistor MN9 as its positive side input, the gate input of the NMOS transistor MN12 as its negative side input, the node A5 as its negative side output, and the node A6 as its positive side output; and
said first to third delay circuits being cascade-connected such that
the negative side output A1 of the first delay circuit is connected to the positive side input of the second delay circuit, and the positive side output A2 of the first delay circuit is connected to the negative side input of the second delay circuit,
the negative side output A3 of the second delay circuit is connected to the positive side input of the third delay circuit, and the positive side output A4 of the second delay circuit is connected to the negative side input of the third delay circuit, and
the negative side output A5 of the third delay circuit is connected to the positive side input of the first delay circuit, and the positive side output A6 of the third delay circuit is connected to the negative side input of the first delay circuit.

9. An oscillation circuit as defined in claim 8, wherein the gate inputs of the NMOS transistors MN13, MN14, MN15, MN16, MN17, and MN18 are an arbitrary constant voltage.

10. An oscillation circuit as defined in any of claims 4 to 9, wherein the number of the delay circuits to be cascade-connected is N (N: integer equal to or larger than 2).
